(19) United States
(12) Patent Application Publication
(10) Pub. No.: US 2026/0262213 A1
(43) Pub. Date: Sep. 3, 2026

(54) THREE-DIMENSIONAL SEMICONDUCTOR DEVICE AND METHOD FOR MANUFACTURING THE SAME

(71) Applicant: Samsung Electronics Co., Ltd., Suwon-si (KR)

(72) Inventors: Jihoon Choi, Suwon-si (KR); Gyuhwan Oh, Suwon-si (KR); Jinwoo Han, Suwon-si (KR); Woochul Kim, Suwon-si (KR); Hyebin Kim, Suwon-si (KR); Eunsuk Jang, Suwon-si (KR)

(21) Appl. No.: 19/431,001

(22) Filed: Dec. 23, 2025

(30) Foreign Application Priority Data
Feb. 28, 2025 (KR) 10-2025-0026958

(51) Int. Cl. H10B 12/00

(52) U.S. Cl. CPC H10B 12/30; H10B 12/03; H10B 12/05

(57) ABSTRACT

A three-dimensional semiconductor device includes: a substrate; first semiconductor patterns disposed on the substrate and spaced apart from each other in a first direction; second semiconductor patterns adjacent to the first semiconductor patterns in a second direction, and spaced apart from each other in the first direction; a lower liner pattern disposed on the substrate and extending in the first direction between the first semiconductor patterns and the second semiconductor patterns; an upper liner pattern extending in the first direction on the lower liner pattern; and bit lines disposed between the first semiconductor patterns and the upper liner pattern, and between the second semiconductor patterns and the upper liner pattern, where the bit lines extend in a third direction on the lower liner pattern.

### CROSS-REFERENCE TO RELATED APPLICATIONS

This U.S. non-provisional patent application claims priority under 35 U.S.C. §119 to Korean Patent Application No. 10-2025-0026958, filed on Feb. 28, 2025, in the Korean Intellectual Property Office, the entire contents of which are hereby incorporated by reference.

### BACKGROUND

A semiconductor device is an important component in the electronics industry due to characteristics such as miniaturization, multi-functionality, and/or low manufacturing cost. The semiconductor device may be classified into multiple categories, including a semiconductor memory device that stores logic data, a semiconductor logic device that calculates and processes the logic data, and a hybrid semiconductor device that includes a memory component and a logic component.

Recently, with the advent of a high speed and low power consumption of electronic apparatuses, a high operation speed, a low operation voltage, and/or the like are also required for the semiconductor device built therein. In order to satisfy such requirements, a more highly-integrated semiconductor device may be needed.

### SUMMARY

When a semiconductor device becomes more highly-integrated, electrical characteristics and production yield of the semiconductor device may be reduced. Accordingly, improvement of the electrical characteristics and the production yield of the semiconductor device may be desired.

The present disclosure provides a three-dimensional semiconductor device with improved electrical characteristics and reliability and a method for manufacturing the same.

In general, in some aspects, the present disclosure provides a three-dimensional semiconductor device that may include a substrate; first semiconductor patterns disposed on the substrate and spaced apart from each other in a first direction parallel to a lower surface of the substrate; second semiconductor patterns adjacent to the first semiconductor patterns in a second direction perpendicular to the first direction and parallel to the lower surface of the substrate, and spaced apart from each other in the first direction; a lower liner pattern disposed on the substrate and extending in the first direction between the first semiconductor patterns and the second semiconductor patterns; an upper liner pattern extending in the first direction on the lower liner pattern; and bit lines disposed between the first semiconductor patterns and the upper liner pattern, and between the second semiconductor patterns and the upper liner pattern, where the bit lines extend in a third direction perpendicular to the first and second directions on the lower liner pattern.

In general, in some aspects, the present disclosure provides a three-dimensional semiconductor device that may include a substrate, first semiconductor patterns disposed on the substrate and spaced apart from each other in a first direction parallel to a lower surface of the substrate, bit lines on first sidewalls of the first semiconductor patterns, data storage pattern on second sidewalls of the first semiconductor patterns opposite to the first sidewalls of the first semiconductor patterns in a second direction, the second direction perpendicular to the first direction and parallel to the lower surface of the substrate, a lower liner pattern between the data storage pattern and the substrate, and an upper liner pattern between the data storage pattern and the lower liner pattern, where the lower liner pattern and the upper liner pattern extend in the first direction.

In general, in some aspects, the present disclosure provides a three-dimensional semiconductor device that may include a substrate, first semiconductor patterns disposed on the substrate and spaced apart from each other in a first direction parallel to a lower surface of the substrate, second semiconductor patterns adjacent to first edge portions of the first semiconductor patterns in a second direction perpendicular to the first direction and parallel to the lower surface of the substrate, third semiconductor patterns adjacent to second edge portions of the first semiconductor patterns in the second direction, a first lower liner pattern disposed on the substrate and extending in the first direction between the first semiconductor patterns and the second semiconductor patterns, a first upper liner pattern disposed on the first lower liner pattern and extending in the first direction, bit lines disposed on the first edge portions of the first semiconductor patterns and extending in a third direction perpendicular to the first and second directions, and data storage pattern extending in the third direction on the second edge portions of the first semiconductor patterns, where the bit lines are disposed between the first edge portions and the first upper liner pattern on the first lower liner pattern.

### BRIEF DESCRIPTION OF THE DRAWINGS

FIG. 1 is a schematic circuit diagram illustrating an example of a three-dimensional semiconductor device.

FIGS. 2A, 2B and 2C are schematic perspective views of an example of a three-dimensional semiconductor device.

FIG. 3 is a plan view of an example of a three-dimensional semiconductor device.

FIG. 4a is a cross-sectional view corresponding to line A-A’ of FIG. 3.

FIG. 4b is a cross-sectional view corresponding to line B-B’ of FIG. 3.

FIG. 5a and FIG. 5b are cross-sectional views of an example of a three-dimensional semiconductor device according to some implementations and corresponding to FIG. 4a.

FIG. 6 is a plan view of an example of a three-dimensional semiconductor device.

FIG. 7a is a cross-sectional view corresponding to line C-C’ of FIG. 6.

FIG. 7b is a cross-sectional view of an example of a three-dimensional semiconductor device according to some implementations and corresponding to FIG. 7a.

FIGS. 8 to 27 are diagrams illustrating a method for manufacturing an example of a three-dimensional semiconductor device.

FIGS. 28 and 29 are diagrams illustrating a method for manufacturing an example of a three-dimensional semiconductor device.

### DETAILED DESCRIPTION

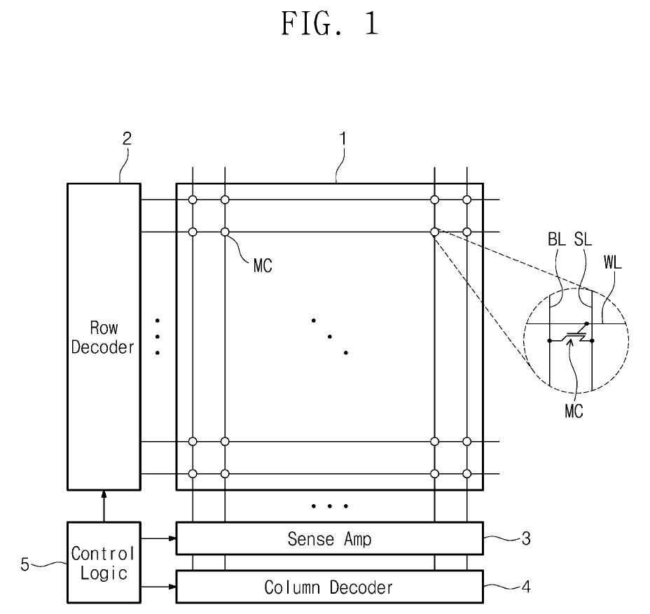

FIG. 1 is a schematic circuit diagram illustrating a three-dimensional semiconductor device according to some implementations.

Referring to FIG. 1, the three-dimensional semiconductor device may include a memory cell array 1, a row decoder 2, a sense amplifier 3, a column decoder 4 and a control logic 5.

The memory cell array 1 may include word lines WL, bit lines BL, source lines SL and memory cells MC. The memory cells MC may be three-dimensionally arranged, and each of the memory cells MC may be connected to one word line WL, one bit line BL, and one source line SL. According to some implementations, each of the memory cells MC may be composed of one transistor including a memory layer (or data storage layer).

The row decoder 2 may decode an address input from the outside and may select one of the word lines WL of the memory cell array 1. The address decoded by the row decoder 2 may be provided to a row driver (not shown), and the row driver may provide a voltage to a selected word line WL and unselected word lines WL in response to controlling of control circuits.

The sense amplifier 3 may sense, amplify and output a voltage difference between a selected bit line BL according to an address decoded by the column decoder 4 and a reference bit line.

The column decoder 4 may provide a data transfer path between the sense amplifier 3 and an external device (for example, a memory controller). The column decoder 4 may select any one among the bit lines BL by decoding an address input from the outside.

The control logic 5 may generate control signals that control operations of writing a data to the memory cell array 1 or reading the data from the memory cell array 1.

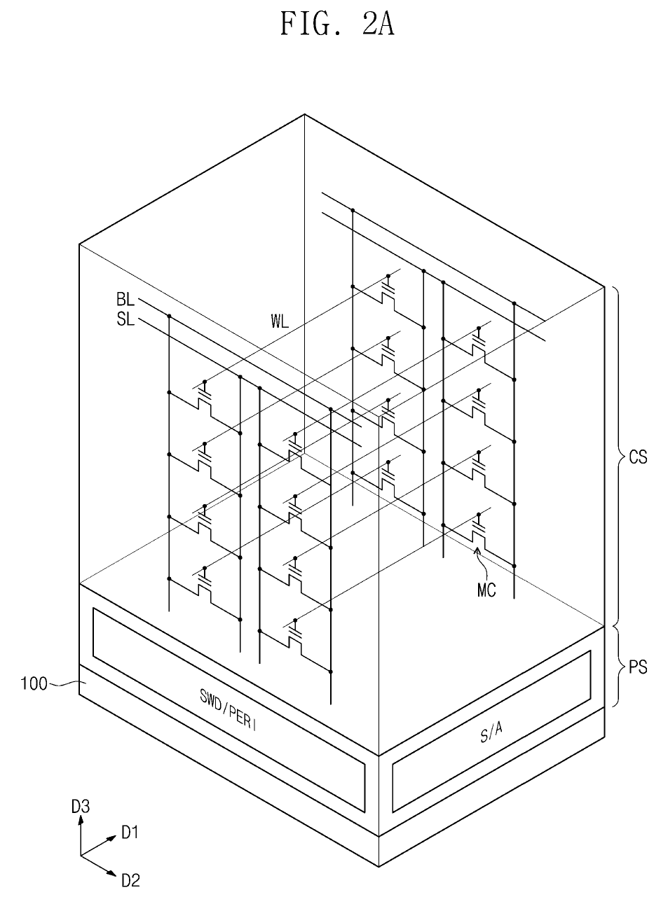

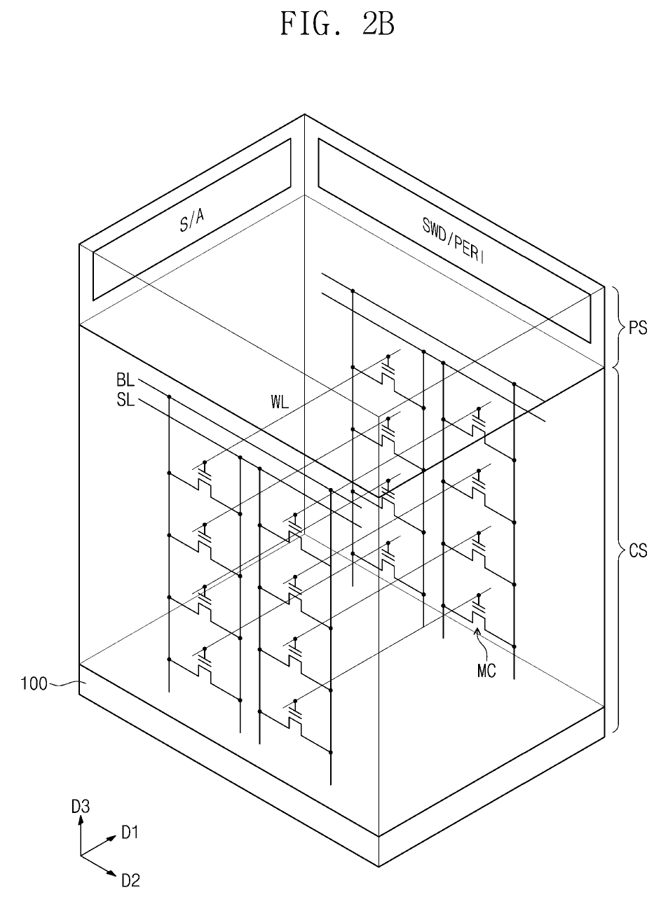

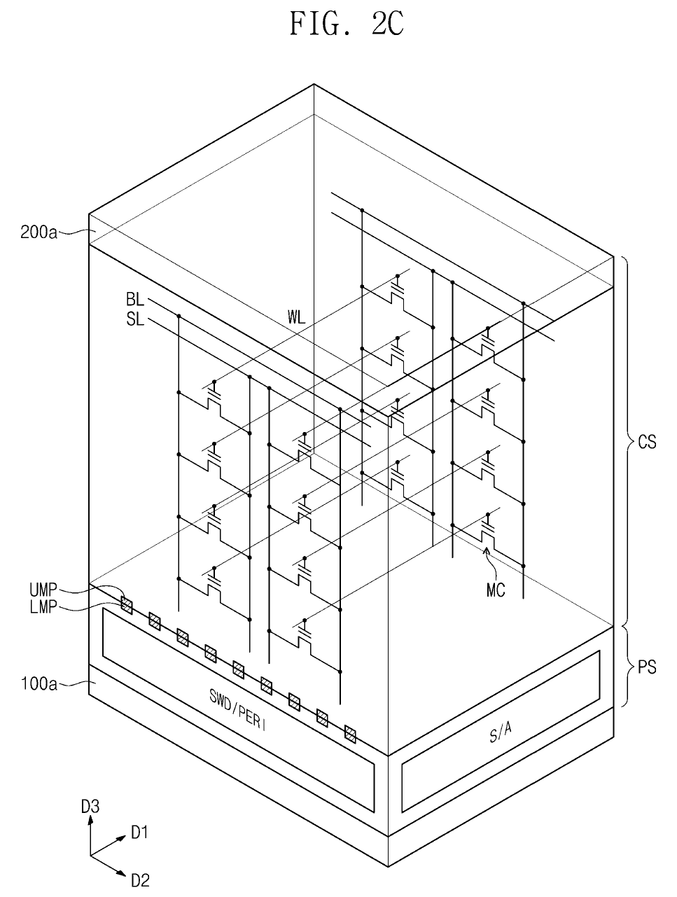

FIGS. 2A, 2B and 2C are schematic perspective views of the three-dimensional semiconductor device according to some implementations.

Referring to FIG. 2A, the three-dimensional semiconductor device may include a substrate 100, a peripheral circuit structure PS on the substrate 100 and a cell array structure CS on the peripheral circuit structure PS.

The peripheral circuit structure PS may include core and peripheral circuits formed on the substrate 100. The core and peripheral circuits may include the row and column decoders 2 and 4 (see FIG. 1), the sense amplifier 3 (see FIG. 1) and the control logic 5 (see FIG. 1) described with reference to FIG. 1.

The substrate 100 may have a shape of a plate expanding along a plane defined by a first direction D1 and a second direction D2. The first direction D1 and the second direction D2 may be parallel to an upper surface of the substrate 100, and may cross each other. For example, the first direction D1 and the second direction D2 may be horizontal directions perpendicular to each other. The peripheral circuit structure PS and the cell array structure CS may be sequentially stacked on the substrate 100 in a third direction D3 perpendicular to the upper surface of the substrate 100.

The cell array structure CS may include the bit lines BL, the source lines SL, the word lines WL and the memory cells MC therebetween. Each of the memory cells MC may be connected to one word line WL, one bit line BL and one source line SL.

Referring to FIG. 2B, the semiconductor device may include the cell array structure CS on the substrate 100, and the peripheral circuit structure PS on the cell array structure CS. The cell array structure CS may be disposed between the substrate 100 and the peripheral circuit structure PS. The peripheral circuit structure PS may include core and peripheral circuits.

Referring to FIG. 2C, the semiconductor device may have a chip-to-chip (C2C) structure. The peripheral circuit structure PS may include a first substrate 100a. Lower metal pads LMP may be provided on an uppermost portion of the peripheral circuit structure PS. The lower metal pads LMP may be electrically connected to the core and peripheral circuits. The lower metal pads LMP may be bonded to upper metal pads UMP of the cell array structure CS.

The cell array structure CS may include a second substrate 200a, and the upper metal pads UMP may be provided on a lowermost portion of the cell array structure CS. The upper metal pads UMP may be electrically connected to the bit lines BL, the source lines SL and the word lines WL. The upper metal pads UMP may be electrically connected to the memory cells MC.

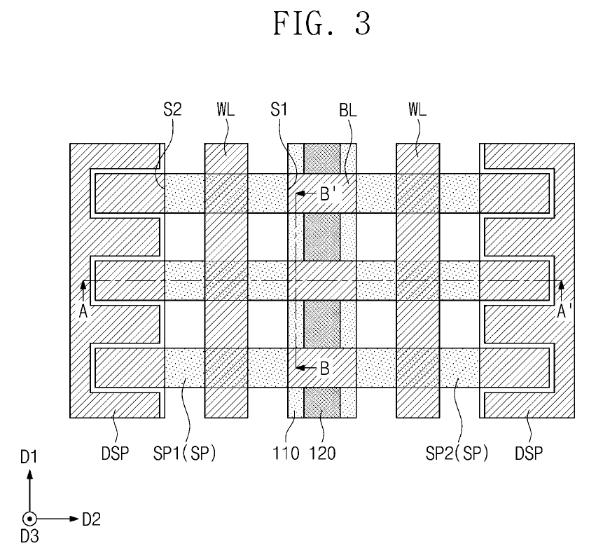

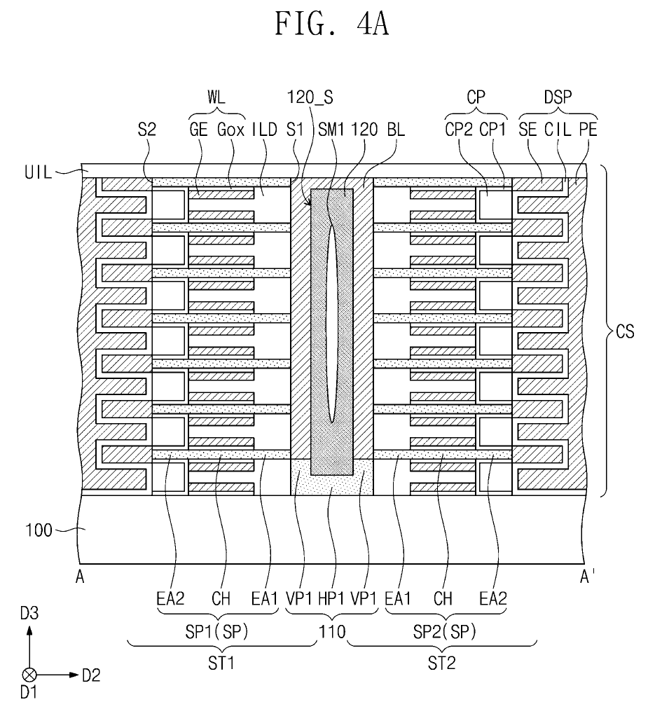

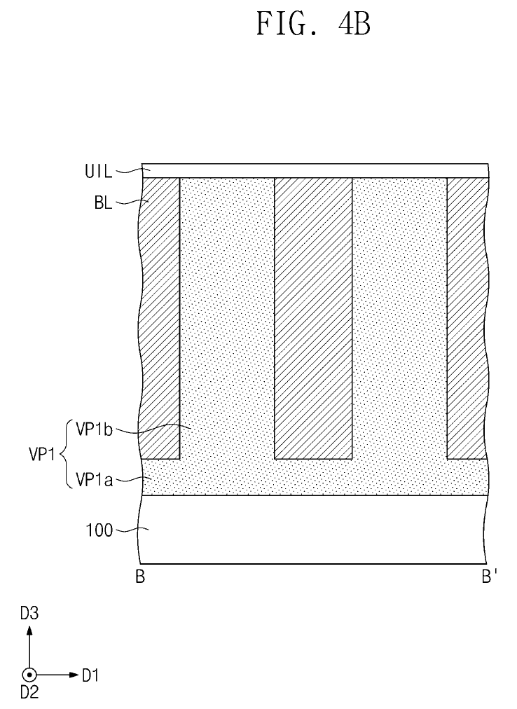

FIG. 3 is a plan view of a three-dimensional semiconductor device according to some implementations. FIG. 4a is a cross-sectional view corresponding to line A-A’ of FIG. 3. FIG. 4b is a cross-sectional view corresponding to line B-B’ of FIG. 3.

Referring to FIGS. 3 and 4a, the three-dimensional semiconductor device may include the substrate 100. For example, the substrate 100 may be a semiconductor substrate, an insulating substrate, a silicon-on-insulator (SOI) substrate or a germanium-on-insulator (GOI) substrate. For example, the semiconductor substrate may be a silicon substrate, a germanium substrate or a silicon-germanium substrate. The substrate 100 may have a shape of a plate expanding along a plane defined by the first direction D1 and the second direction D2. The first direction D1 and the second direction D2 may be directions parallel to a lower surface of the substrate 100, and may cross each other. For example, the substrate 100 may include the peripheral circuit structure PS described with reference to FIGS. 2A and 2C.

The cell array structure CS may be provided on the substrate 100.. In some implementations, the cell array structure CS may include a plurality of cell array structures CS adjacent to each other in the second direction D2. Hereinafter, for convenience of description, a single cell array structure CS will be described, but the description below may be identically applied to another cell array structure CS.

The cell array structure CS may include a first stack structure ST1 and a second stack structure ST2 adjacent to each other in the second direction D2. Each of the first stack structure ST1 and the second stack structure ST2 may include semiconductor patterns SP, word lines WL and peripheral components surrounding the semiconductor patterns SP and the word lines WL. Each of the semiconductor patterns SP, the word lines WL and the peripheral components will be specifically described below.

The semiconductor pattern SP may be spaced apart from the substrate 100 in the third direction D3. In other words, the semiconductor pattern SP may be floated from the substrate 100. The semiconductor pattern SP may extend on the substrate 100 along the second direction D2. For example, the semiconductor pattern SP may have a shape of a bar extending along the second direction D2.

The semiconductor pattern SP may include a first edge portion EA1 and a second edge portion EA2 spaced apart from each other in the second direction D2, and a channel region CH therebetween. The channel region CH of the semiconductor pattern SP may vertically overlap the word line WL to be described later. The first edge portion EA1 of the semiconductor pattern SP may be connected to a bit line BL to be described later. The second edge portion EA2 may be connected to a data storage pattern DSP to be described later. In the present specification, the wording, ‘A and B are connected to each other’ may include not only that A and B are in direct contact with each other, but also that A and B are indirectly connected to each other through C (for example, a component having conductivity) between A and B. Here, component C may be a single component or a plurality of components.

The semiconductor pattern SP may include at least one of single-crystalline semiconductor, polycrystalline semiconductor, oxide semiconductor, and a two-dimensional material. For example, the single-crystalline semiconductor may be single-crystalline silicon. For example, the polycrystalline semiconductor may be polysilicon. For example, the oxide semiconductor may be indium-gallium-zinc oxide (IGZO). For example, the two-dimensional material may be MoS₂, WS₂, MoSe₂ or WSe₂. In the present specification, each of wordings such as “A or B”, “at least one of A and B”, “at least one of A or B”, “A, B or C”, “at least one of A, B and C”, and “at least one of A, B or C” may include any one of listed, or all possible combinations therebetween.

For example, each of the first and second edge portions EA1 and EA2 of the semiconductor pattern SP may include an impurity region doped with impurities (for example, an N-type or P-type impurity) therein. The impurity region may constitute a source/drain region of a transistor.

The semiconductor pattern SP may be provided in plurality. The semiconductor patterns SP may be spaced apart from each other along the first direction D1 and the third direction D3. For example, upper surfaces of the semiconductor patterns SP disposed along the first direction D1 may be aligned with each other. The semiconductor patterns SP disposed along the third direction D3 may vertically overlap each other. For example, sidewalls of the semiconductor patterns SP disposed along the third direction D3 may be aligned with each other.

The semiconductor pattern SP may include first semiconductor patterns SP1 provided in the first stack structure ST1 and second semiconductor patterns SP2 provided in the second stack structure ST2. The first semiconductor patterns SP1 may be spaced apart from each other along the first direction D1 and the third direction D3. The second semiconductor patterns SP2 may be spaced apart from each other along the first direction D1 and the third direction D3. The first semiconductor patterns SP1 may be spaced apart from the second semiconductor patterns SP2 in the second direction D2. The first edge portions EA1 of the first semiconductor patterns SP1 may be closer to the first edge portions EA1 of the second semiconductor patterns SP2 than the second edge portions EA2 of the second semiconductor patterns SP2. Each of the first semiconductor patterns SP1 may have a first sidewall S1 and a second sidewall S2 that are opposite to each other. The first sidewall S1 may refer to a sidewall of the first edge portion EA1, and the second sidewall S2 may refer to a sidewall of the second edge portion EA2. The first sidewalls S1 may be aligned with each other along the third direction D3 and the second sidewalls S2 may be aligned with each other along the third direction D3. The bit line BL, which will be specifically described below, may be disposed on the first sidewalls S1 of the first semiconductor patterns SP1. The data storage pattern DSP, which will be specifically described below, may be disposed on the second sidewalls S2 of the first semiconductor patterns SP1.

The word line WL may surround the channel regions CH of the semiconductor patterns SP spaced apart from each other along the first direction D1, and may extend along the first direction D1. The word line WL may be provided in plurality. The word lines WL may be spaced apart from each other in the third direction D3.

The word line WL may include a gate insulating pattern GI surrounding the channel region CH of the semiconductor pattern SP, and a gate pattern GE extending on the gate insulating pattern GI along the first direction D1. For example, the gate insulating pattern GI may include a high-dielectric layer, a silicon oxide layer, a silicon nitride layer, a silicon oxynitride layer, or a combination thereof. In the present specification, a high-k material is defined as a material having a higher dielectric constant than silicon oxide.

For example, the gate pattern GE may include at least one of Ti, TiN, TiSiN, TiON, W, WN, Mo, MoN, MoOₓN_{y}, Ta, TaN, Poly Si, Li, Na, K, Cs, Rb, Sr, Ba, Ca, Ce, Sm, Eu, Mg, Sc, Y, Hf, Tl, As, La, Nd, Gd, Tb, Lu, Th, U, Mn, Al, Ga, In, Pb, Cd, Bi and Zr. For example, the gate pattern GE may be a single layer or a composite layer.

A first lower liner pattern 110 may be interposed between the first semiconductor patterns SP1 and the second semiconductor patterns SP2. In other words, the first lower liner pattern 110 may be provided within a trench defined between the first semiconductor patterns SP1 and the second semiconductor patterns SP2, which are adjacent to each other in the second direction D2. The first lower liner pattern 110 may extend in the first direction D1. A portion of the first lower liner pattern 110 may overlap with the bit lines BL in a plan view. The first lower liner pattern 110 may cover a portion of the upper surface of the substrate 100.

Referring to FIGS. 3, 4a and 4b, the first lower liner pattern 110 may include a first horizontal part HP1 and first vertical parts VP1. The first horizontal part HP1 may refer to a portion that vertically overlaps a first upper liner pattern 120. The first horizontal part HP1 may be provided between the first upper liner pattern 120 and the substrate 100. The first vertical parts VP1 may refer to a portion extending along the third direction D3 from both ends of the first horizontal part HP1 in the second direction D2. The first vertical parts VP1 may extend along the third direction D3 and may cover a portion of a sidewall 120_S of the first upper liner pattern 120.

The first vertical part VP1 may include a first part VP1a that vertically overlaps the bit line BL, and a second part VP1b that does not vertically overlap the first part VP1a and the bit line BL. The second part VP1b may be adjacent to the first part VP1a in the first direction D1. For example, the first part VP1a and the second part VP1b may be alternately arranged along the first direction D1. An upper surface of the first part VP1a may be located at a lower level than an upper surface of the second part VP1b. For example, the upper surface of the second part VP1b may be coplanar with an upper surface of the bit line BL.

The first upper liner pattern 120 may be disposed on the first lower liner pattern 110. The first upper liner pattern 120 may extend in the first direction D1 on the first lower liner pattern 110. The bit line BL and the first lower liner pattern 110 may be disposed on the sidewall 120_S of the first upper liner pattern 120. For example, the first upper liner pattern 120 may include a first void SM1 formed therein. The first void SM1 may refer to a seam formed inside the first upper liner pattern 120. For another example, the first void SM1 may not be formed inside the first upper liner pattern 120.

The first lower liner pattern 110 and the first upper liner pattern 120 may include different materials. For example, the first lower liner pattern 110 and the first upper liner pattern 120 may include materials that differ in etching selectivity. For example, the first lower liner pattern 110 may include silicon oxide and the first upper liner pattern 120 may include at least one of silicon nitride, silicon carbide, and polysilicon. The first upper liner pattern 120 may further include silicon oxide.

The bit lines BL may be interposed between the first semiconductor patterns SP1 and the second semiconductor patterns SP2. The bit lines BL may be disposed between the first edge portions EA1 of the first semiconductor patterns SP1 and one sidewall 120_S of the first upper liner pattern 120, and between the first edge portion EA1 of the second semiconductor patterns SP2 and another sidewall 120_ S of the first upper liner pattern 120. Specifically, the bit lines BL may extend along the third direction D3 on the first lower liner pattern 110 (especially, on the first vertical part VP1). The bit lines BL may extend on sidewalls of the first edge portions EA1 of the first semiconductor patterns SP1. The bit lines BL may be connected to the first edge portions EA1 of the first semiconductor patterns SP1 along the second direction D2. The bit lines BL may extend on sidewalls of the first edge portions EA1 of the second semiconductor patterns SP2 along the third direction D3. The bit lines BL may be connected to the first edge portions EA1 of the first semiconductor patterns SP1 along the second direction D2.

For example, each of the bit lines BL may connect first semiconductor patterns SP1 and second semiconductor patterns SP2 which are adjacent each other in the second direction D2. In other words, in a cross-sectional view, the bit line BL may have an inverted U-shaped profile. In some examples, the bit lines BL may traverse the first lower liner pattern 110 and the first upper liner pattern 120 along the second direction D2, respectively, and may cover the upper surface of the first upper liners pattern 120.

The bit line BL may be a single layer including one material or a composite layer including at least two materials. For example, the bit line BL may include at least one of a metal material (e.g., Ti, Mo, W, Cu, Al, Ta, Ru, Ir, Co, or the like), metal nitride (e.g., nitride of Ti, Mo, W, Cu, Al, Ta, Ru, Ir, Co, or the like), and metal silicide (e.g., silicide of Ti, Mo, W, Cu, Al, Ta, Ru, Ir, Co, or the like).

An interlayered insulating layer ILD may be interposed between the word lines WL spaced apart from each other in the third direction D3, and may separate the word lines WL from each other. The interlayered insulating layer ILD may be interposed between the bit line BL and the word line WL, and may separate the bit line BL and the word line WL. The interlayered insulating layer ILD may be interposed between the semiconductor patterns SP spaced apart from each other in the third direction D3. A sidewall of a lower portion of the interlayered insulating layer ILD may be covered by the first lower liner pattern 110. The interlayered insulating layer ILD may include an insulating material, and may include, for example, at least one of silicon oxide and silicon nitride.

The data storage pattern DSP may extend along the third direction D3 on side surfaces of the second edge portions EA2 of the semiconductor patterns SP spaced apart from each other along the third direction D3. The data storage pattern DSP may be connected to the second edge portions EA2 of the semiconductor patterns SP.

The data storage pattern DSP may include a storage electrode SE, a plate electrode PE and a dielectric layer CIL therebetween. For example, the three-dimensional semiconductor device may be a dynamic random access memory (DRAM), and in this case, the data storage pattern DSP may be a capacitor. The storage electrode SE may be spaced apart from the plate electrode PE by the dielectric layer CIL therebetween.

Each of the storage electrode SE and the plate electrode PE may include a conductive material. For example, each of the storage electrode SE and the plate electrode PE may include at least one of impurity-doped silicon (Si), impurity-doped silicon germanium (SiGe), a metal material (e.g., Ti, Mo, W, Cu, Al, Ta, Ru, Ir, Co, Pt, Au, Ag, or the like), metal nitride (e.g., nitride of Ti, Mo, W, Cu, Al, Ta, Ru, Ir, Co, Pt, Au, Ag, or the like, titanium silicon nitride (e.g., TiSiN), titanium aluminum nitride (e.g., TiAlN), or tantalum aluminum nitride (e.g., TaAlN or the like)), conductive oxide (e.g., PtO, RuO₂, IrO₂, SRO (SrRuO₃), BSRO ((Ba,Sr)RuO₃), CRO (CaRuO₃), LSCo), and metal silicide. Each of the storage electrode SE and the plate electrode PE may be a single layer composed of a single material or a composite layer including at least two materials.

For example, the dielectric layer CIL may include at least one of metal oxide such as HfO₂, ZrO₂, Al₂O₃, La₂O₃, Ta₂O₃, and TiO₂, or a dielectric material, having a perovskite structure, such as SrTiO₃ (STO), (Ba,Sr)TiO₃ (BST), BaTiO₃, PZT, and PLZT.

For another example, the data storage pattern DSP may be a variable resistance pattern capable of being switched to two resistance states by an electrical pulse. In this case, the data storage pattern DSP may include a phase-change material changing a crystalline state according to an amount of current, a perovskite compound, transition metal oxide, a magnetic material, a ferromagnetic material or an anti-ferromagnetic material.

Although not shown, a silicide pattern (not shown) may be provided between the storage electrode SE and the semiconductor pattern SP. The silicide pattern may include metal silicide (for example, silicide of Ti, Mo, W, Cu, Al, Ta, Ru, Ir, Co or the like). The storage electrode SE may be provided in plurality, and the storage electrodes SE may be adjacent to each other in the third direction D3.

A capping pattern CP may be interposed between the word line WL and the data storage pattern DSP, and may space the same apart from each other. The capping pattern CP may include a first capping pattern CP1 between the word line WL and the data storage pattern DSP, and a second capping pattern CP2 between the first capping pattern CP1 and the data storage pattern DSP. The capping pattern CP may include an insulating material, and may include, for example, at least one of silicon oxide and silicon nitride.

The upper insulating layer UIL may be provided on upper surfaces of the first stack structure ST1 and the second stack structure ST2. The upper insulating layer UIL may cover the data storage pattern DSP, the word lines WL, and the bit lines BL. The upper insulating layer UIL may be a single layer or a composite layer including an insulating material. A plurality of upper wirings (not shown) may be included in the upper insulating layer UIL. A portion of the upper wirings may be electrically connected with the bit line BL, and other portion of the upper wirings may be electrically connected to the data storage pattern DSP.

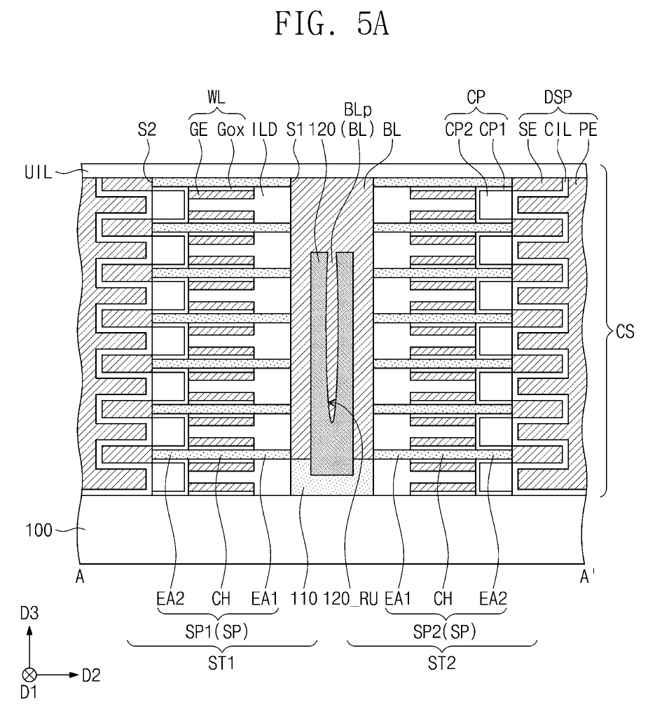

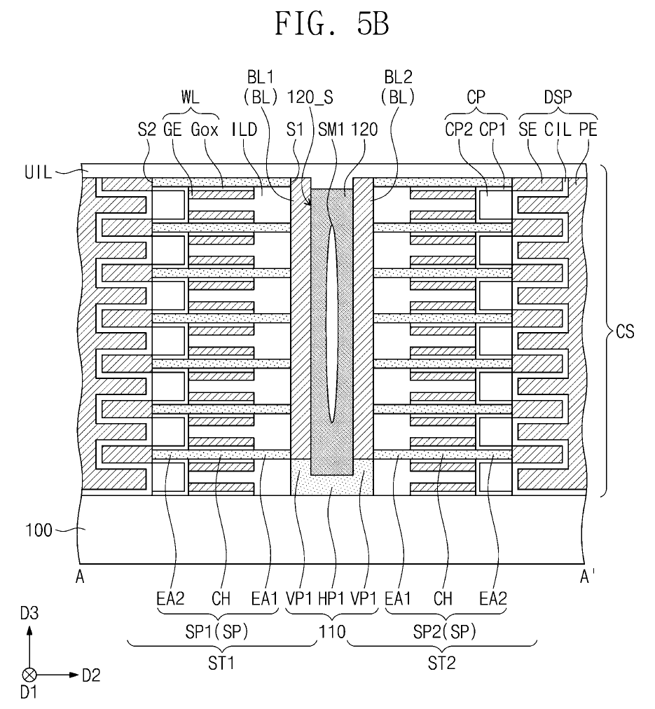

FIGS. 5a and 5b are a cross-sectional view of a three-dimensional semiconductor device according to some implementations and corresponding to FIG. 4a. In order to simplify description, duplicate description will be omitted, and differences from the above will be mainly described.

Referring to FIG. 5A, the first upper liner pattern 120 may have a recessed upper surface 120_RU that is recessed toward the substrate 100. In other words, the first upper liner pattern 120 may have a shape of a recessed top. For example, the recessed upper surface 120_RU of the first upper liner pattern 120 may have a shape of a circle, or an ellipse, in a plan view. For example, the recessed upper surface 120_RU of the first upper liner pattern 120 may have a U-shape in a cross-sectional view.

Each of the bit lines BL may include a first protrusion part BLp that protrudes toward the recessed upper surface 120_RU of the first upper liner pattern 120. The first protrusion part BLp may be a portion of the bit line BL and may extend along the third direction D3 to cover the recessed upper surface 120_RU of the first upper liner pattern 120. The first protrusion part BLp of the bit line BL may be spaced apart from the first edge portions EA1 of the first and second semiconductor patterns SP1, SP2.

Referring to FIG. 5B, each of the bit lines BL may include a first bit line BL1 and a second bit line BL2 spaced apart from each other along the second direction D2. The first bit line BL1 and second bit lines BL2 may be spaced apart from each other with the first upper liner pattern 120 and the upper insulating layer UIL therebetween. The first bit lines BL1 may be connected to the first edge portions EA1 of the first semiconductor patterns SP1. The first bit lines BL1 may be spaced apart from each other along the first direction D1. The second bit lines BL2 may be connected to the first edge portions EA1 of the second semiconductor patterns SP2. The second bit lines BL2 may be spaced apart from each other along the first direction D1.

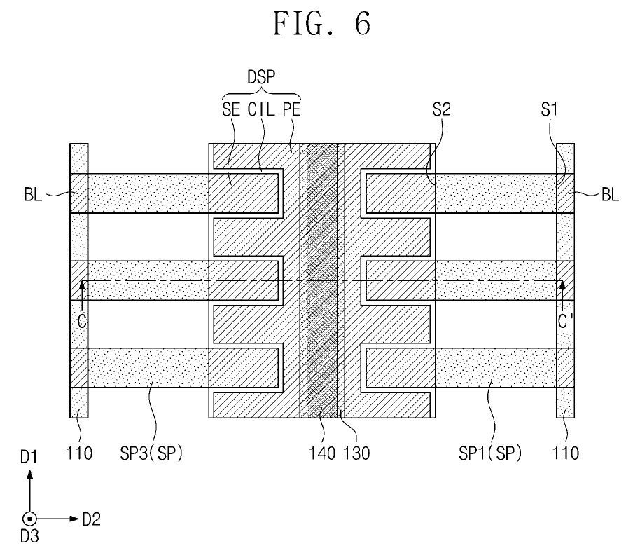

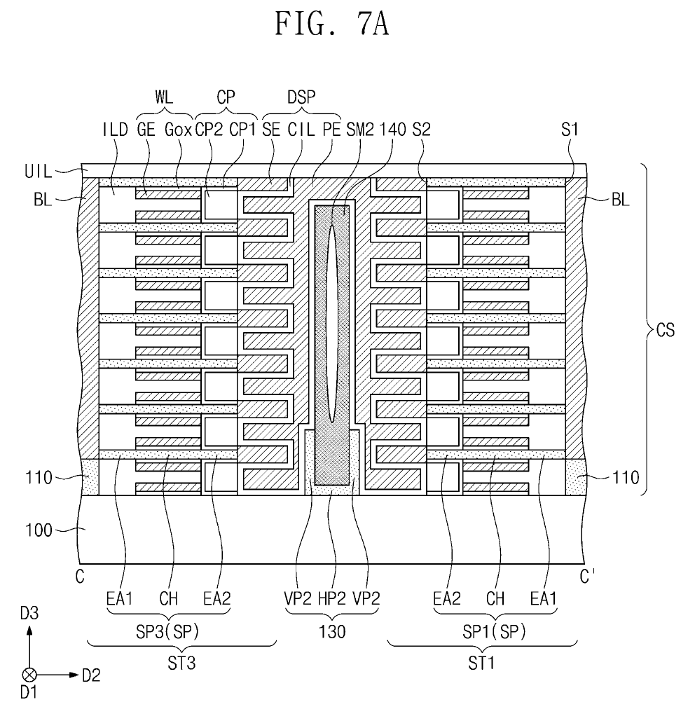

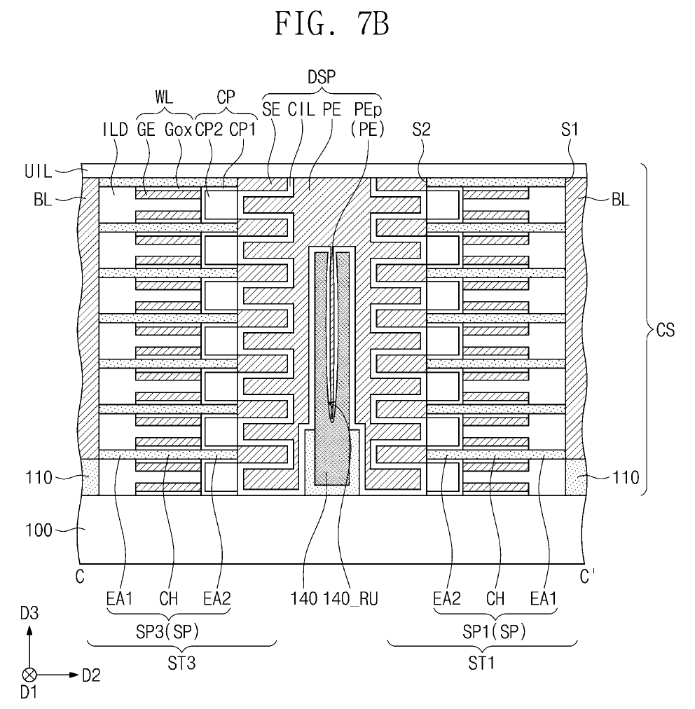

FIG. 6 is a plan view of a three-dimensional semiconductor device according to some implementations. FIG. 7a is a cross-sectional view corresponding to line C-C’ of FIG. 6.

The cell array structure CS may comprise a third stack structure ST3 adjacent to the first stack structure ST1 in the second direction D2. The third stack structure ST3 may include the third semiconductor patterns SP3, the word lines WL, and peripheral components surrounding the third semiconductor patterns SP3 and the word lines WL.

Each of the third semiconductor patterns SP3 may include a first edge portion EA1 and a second edge portion EA2 spaced apart along the second direction D2, and a channel region CH therebetween. The channel regions CH of the third semiconductor patterns SP3 may vertically overlap the word line WL. The first edge portions EA1 of the third semiconductor patterns SP3 may be connected to the bit lines BL. The second edge portions EA2 of the third semiconductor patterns SP3 may be connected to the data storage pattern DSP. The second edge portions EA2 of the third semiconductor patterns SP3 may be closer to the second sidewalls S2 of the first semiconductor patterns SP1 than the first sidewalls S1 of the first semiconductor patterns SP1.

The third semiconductor patterns SP3 may be spaced apart from each other along the first direction D1 and the third direction D3. For example, upper surfaces of the third semiconductor patterns SP3 disposed along the first direction D1 may be aligned with each other. The third semiconductor patterns SP3 disposed along the third direction D3 may vertically overlap each other. For example, sidewalls of the third semiconductor patterns SP3 disposed along the third direction D3 may be aligned with each other. The third semiconductor patterns SP3 may include at least one of single-crystalline semiconductor, polycrystalline semiconductor, oxide semiconductor, and a two-dimensional material.

The word line WL may extend along the first direction D1 and surround the channel regions CH of the third semiconductor patterns SP3 which are spaced apart from each other along the first direction D1. The word line WL may be provided in plurality. The word lines WL may be spaced apart from each other in the third direction D3.

The data storage pattern DSP may extend along the third direction D3 on side surfaces of the second edge portions EA2 of the semiconductor patterns SP spaced apart from each other along the third direction D3. The data storage pattern DSP may be connected to the second edge portions EA2 of the first and third semiconductor patterns SP1, SP3.

The data storage pattern DSP may include a storage electrode SE, a plate electrode PE and a dielectric layer CIL therebetween. For example, the three-dimensional semiconductor device may be a dynamic random access memory (DRAM), and in this case, the data storage pattern DSP may be a capacitor. The storage electrode SE may be spaced apart from the plate electrode PE by the dielectric layer CIL therebetween.

A second lower liner pattern 130 and a second upper liner pattern 140 may be provided between the data storage pattern DSP and the substrate 100. The second lower liner pattern 130 and the second upper liner pattern 140 may be provided between the plate electrode PE and the substrate 100. The data storage pattern DSP may cover upper surfaces of the second lower liner pattern 130 and the second upper liner pattern 140. For example, the plate electrode PE may vertically overlap the second lower liner pattern 130 and the second upper liner pattern 140.

The second lower liner pattern 130 may extend along the first direction D1 on the substrate 100 and cover the upper surface of the substrate 100. The second lower liner pattern 130 may include a second horizontal part HP2 and second vertical parts VP2. The second horizontal part HP2 may vertically overlap the second upper liner pattern 140, and the second vertical parts VP2 may be portions extending along the third direction D3 from both ends of the second horizontal part HP2 along the second direction D2. The second vertical parts VP2 may partially cover a sidewall of the second upper liner pattern 140.

The second upper liner pattern 140 may extend along the first direction D1 on the second lower liner pattern 130. The second horizontal part HP2 of the second lower liner pattern 130 may be interposed between the second upper liner pattern 140 and the substrate 100. The plate electrode PE may be disposed on an upper surface and sidewalls of the second upper liner pattern 140. For example, the second upper liner pattern 140 may include a second void SM2 formed therein. The second void SM2 may refer to a seam formed inside the second upper liner pattern 140. For another example, the second void SM2 may not be formed inside the second upper liner pattern 140.

The second lower liner pattern 130 and the second upper liner pattern 140 may include different materials. For example, the second lower liner pattern 130 and the second upper liner pattern 140 may include materials that differ in etching selectivity. For example, the second lower liner pattern 130 may include silicon oxide and the second upper liner pattern 140 may include at least one of silicon nitride, silicon carbide, and polysilicon. The second upper liner pattern 140 may further include silicon oxide.

The dielectric layer CIL may be interposed between the second lower liner pattern 130 and the plate electrode PE, and between the second upper liner pattern 140 and the plate electrode PE. The dielectric layer CIL may cover sidewalls of the second lower liner pattern 130 and the second upper liner pattern 140.

FIG. 7b is a cross-sectional view of a three-dimensional semiconductor device according to some implementations and corresponding to FIG. 7a. In order to simplify description, duplicate description will be omitted, and a difference from the above will be mainly described.

Referring to FIG. 7B, the second upper liner pattern 140 may have a recessed upper surface 140_RU that is recessed toward the substrate 100. In other words, the second upper liner pattern 140 may have a shape of a recessed top. For example, the recessed upper surface 140_RU of the second upper liner pattern 140 may have a shape of a circle, or an ellipse, in a plan view. For example, the recessed upper surface 140_RU of the second upper liner pattern 140 may have a U-shape in a cross-sectional view.

The plate electrode PE may include a second protrusion part PEp that protrudes toward the recessed upper surface 140_RU of the second upper liner pattern 140. The second protrusion part PEp may be portion of the plate electrode PE and may extend along the third direction D3 to cover the recessed upper surface 140_RU of the second upper liner pattern 140. The second protrusion part PEp of the plate electrode PE may be spaced apart from the second edge portions EA2 of the first and third semiconductor patterns SP1, SP3.

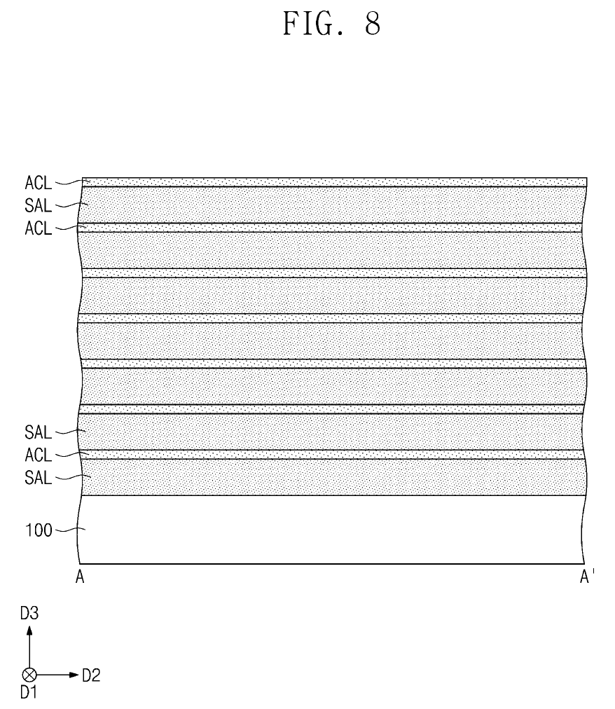

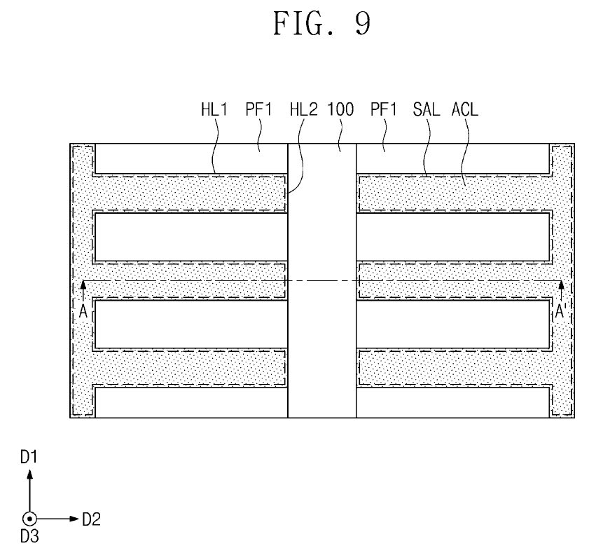

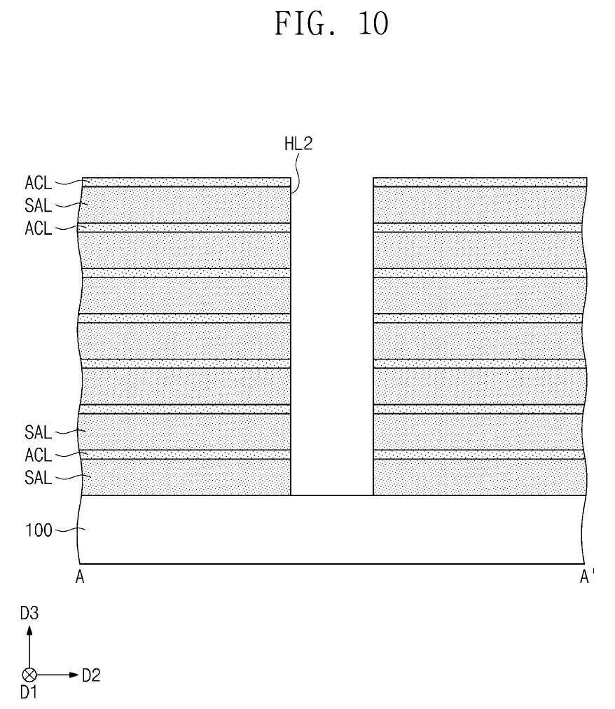

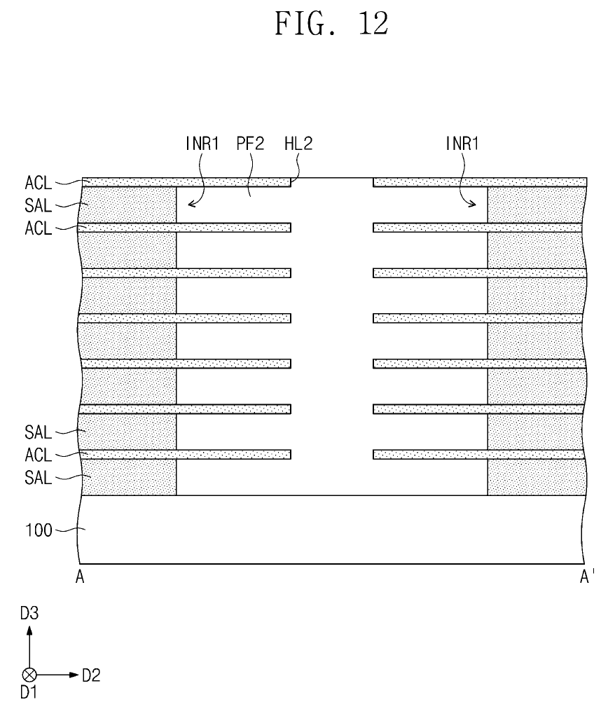

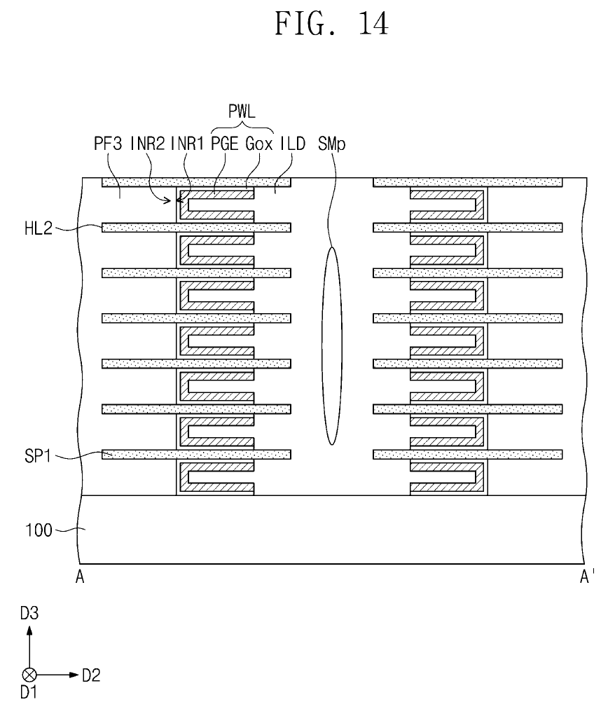

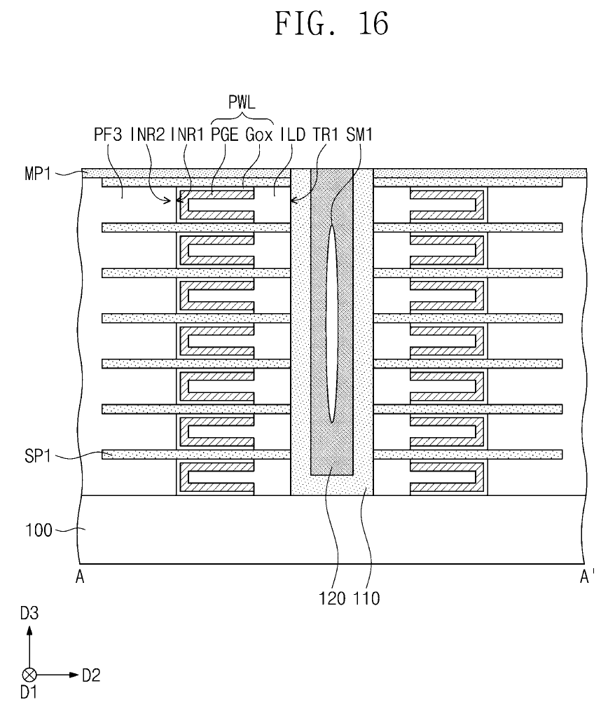

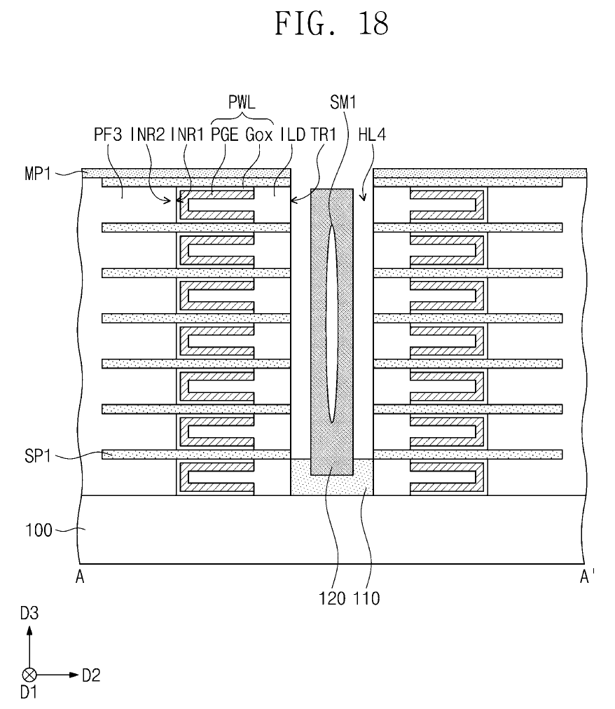

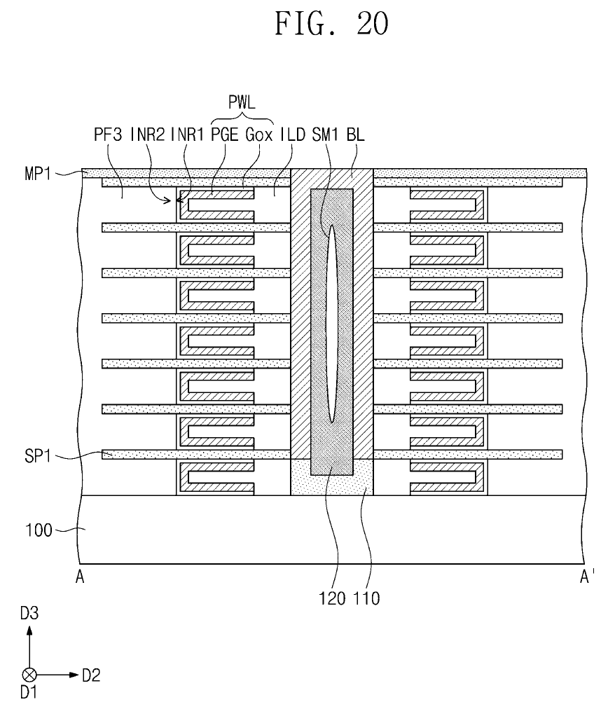

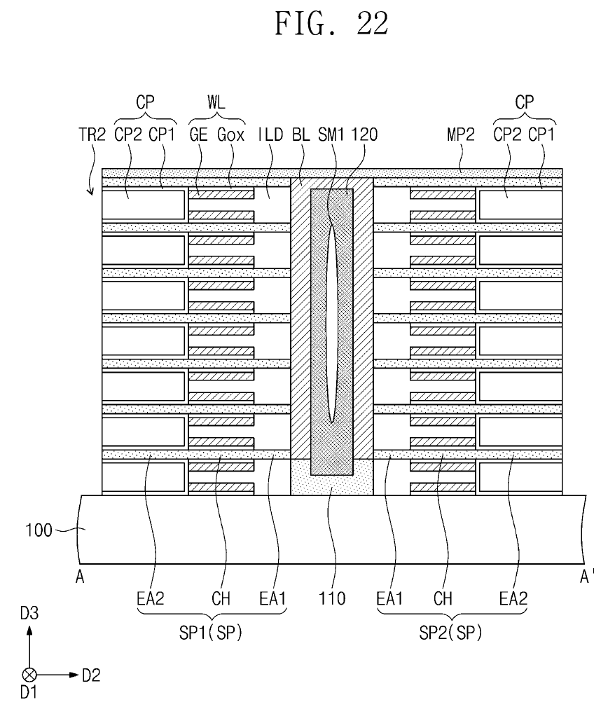

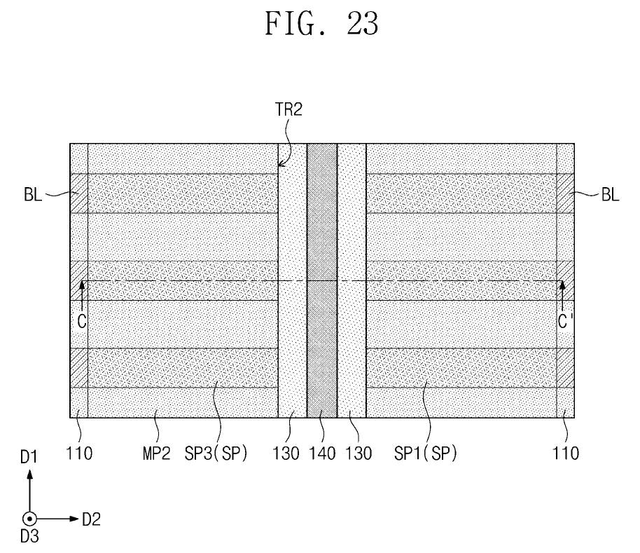

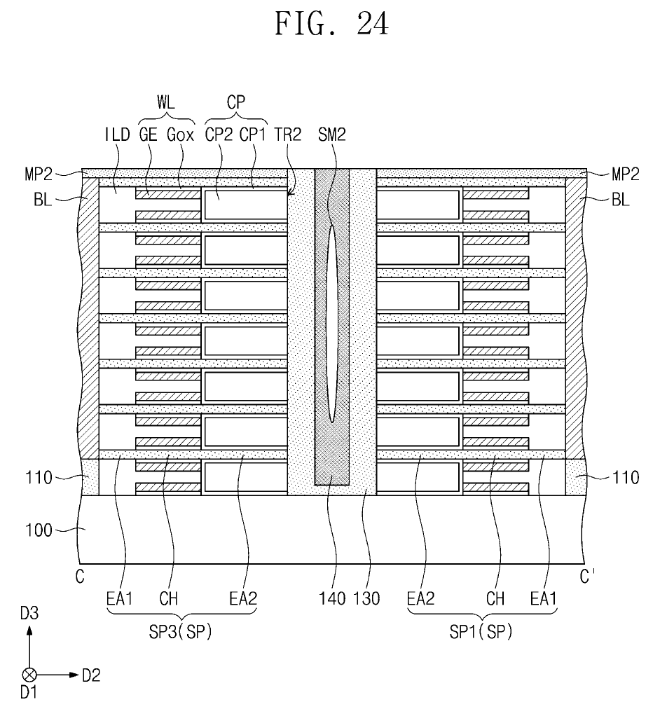

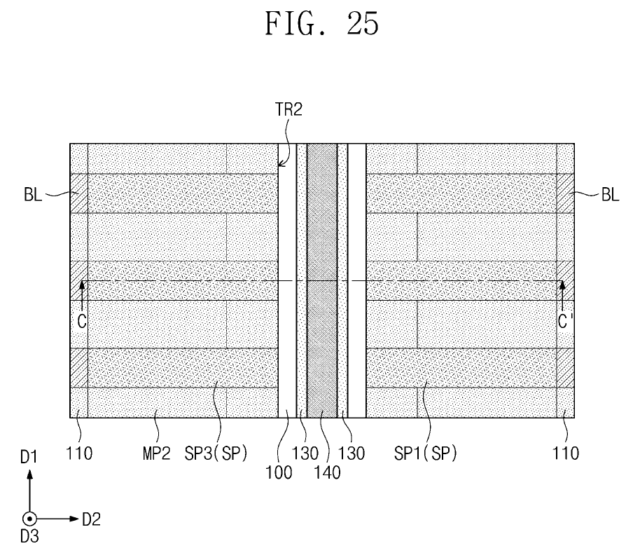

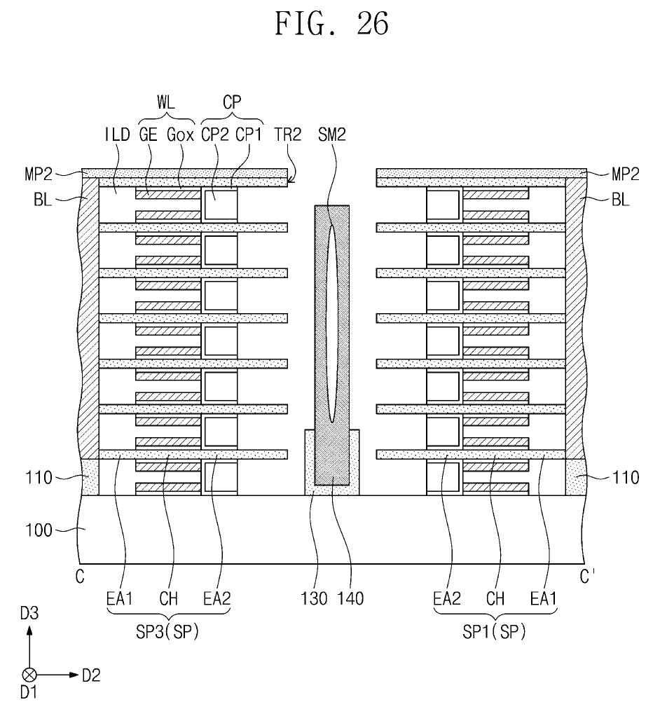

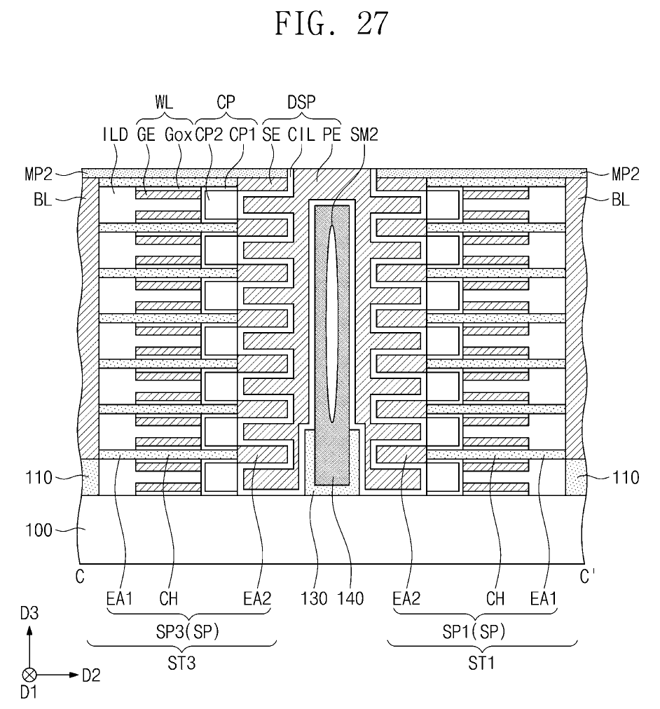

FIGS. 8 to 27 are diagrams illustrating a method for manufacturing a three-dimensional semiconductor device according to some implementations. Specifically, FIGS. 9, 11, 13, 15, 17, 19, and 21 are plan views of a three-dimensional semiconductor device according to some implementations according to some implementations, respectively. FIG. 10, FIG. 12, FIG. 14, FIG. 16, FIG. 18, FIG. 20, and FIG. 22 are cross-sectional views corresponding to lines A-A′ in FIGS. 9, 11, 13, 15, 17, 19, and 21, respectively. FIGS. 23 and 25 are plan views illustrating a three-dimensional semiconductor device according to some implementations, respectively. FIGS. 24 and 26 are cross-sectional views corresponding to lines C-C′ in FIGS. 23 and 25, respectively. FIG. 27 is a cross-sectional view corresponding to FIG. 26.

Referring to FIG. 8, the substrate 100 may be prepared. Sacrificial layers SAL and active layers ACL may be alternately stacked on the substrate 100. Each of the sacrificial layers SAL and the active layers ACL may include a semiconductor material. The sacrificial layers SAL may include a material capable of having etching selectivity for the active layers ACL. Accordingly, during a process of removing the sacrificial layers SAL, to be described later, although the sacrificial layers SAL are removed, the active layers ACL may not be removed, or may be removed less than the sacrificial layers SAL. For example, the active layers ACL may include one of silicon (Si), germanium (Ge) and silicon-germanium (SiGe), and the sacrificial layers SAL may include another one of silicon (Si), germanium (Ge) and silicon-germanium (SiGe). For example, the active layers ACL may include silicon (Si), and the sacrificial layers SAL may include silicon-germanium (SiGe). In some examples, with respect to the third direction D3, the sacrificial layers SAL may have a greater thickness than the active layers ACL.

Referring to FIG. 9 and 10, first holes HL1 may be formed on the substrate 100 by partially removing each of the sacrificial layers SAL and the active layers ACL. The first holes HL1 may be formed to be adjacent to each other in the first direction D1 and the second direction D2. The upper surface of the substrate 100 may be partially exposed to the outside by the first holes HL1. Each of the sacrificial layers SAL and the active layers ACL may be formed to include regions extending along in the first direction D1, and regions extending along in the second direction D2 through the removing process.

First preliminary filling patterns PF1 may cover the exposed portion of the upper surface of the substrate 100, and may be formed so as to fill insides of the first holes HL1. For example, the first preliminary filling patterns PF1 may include an insulating material. The first preliminary filling patterns PF1 may be formed so as to be adjacent to each other in the first direction D1 and the second direction D2.

Second holes HL2 may be formed on the substrate 100 by partially removing the sacrificial layers SAL and the active layers ACL. The second holes HL2 may extend along the first direction D1. Both side surfaces of the sacrificial layers SAL and the active layers ACL may be exposed to the outside by the second holes HL2. The upper surface of the substrate 100 may be partially exposed to the outside by the second holes HL2.

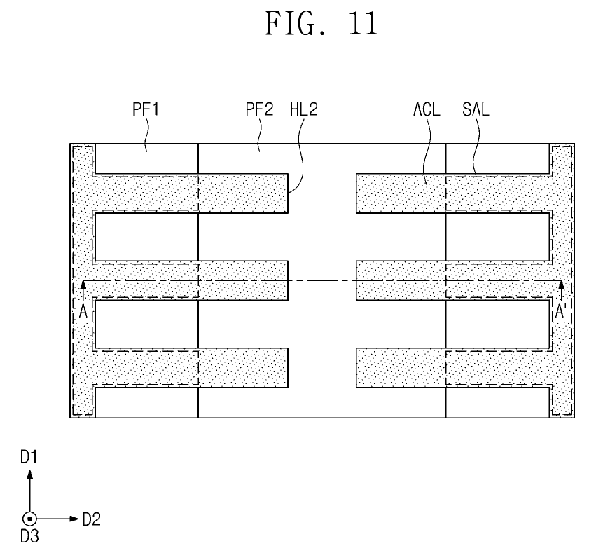

Referring to FIG. 11 and 12, the exposed both side surfaces of the sacrificial layers SAL may be selectively removed through the second holes HL2. Accordingly, first inner regions INR1 may be formed between the active layers ACL disposed along the third direction D3. Each of the first preliminary filling patterns PF1 may be partially removed together during the removing process. Sidewalls of the first preliminary filling patterns PF1 may be aligned with sidewalls of the sacrificial layers SAL.

Second preliminary filling patterns PF2 may be formed to fill the first inner regions INR1, a region in which the first preliminary filling patterns PF1 are partially removed, and the insides of the second holes HL2. The second preliminary filling patterns PF2 may surround and cover the active layers ACL not vertically overlapping the sacrificial layers SAL. The second preliminary filling patterns PF2 may include a single layer or a composite layer including an insulating material. For example, the second preliminary filling patterns PF2 may include at least one of silicon oxide and silicon nitride.

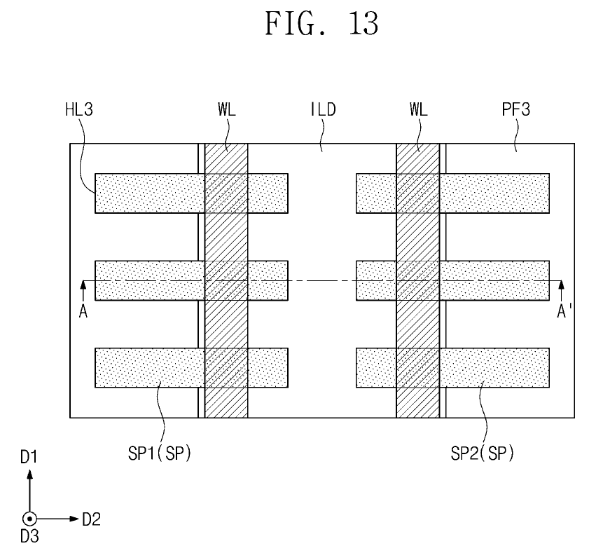

Referring to FIGS. 13 and 14, third holes HL3 may be formed on the substrate 100 by removing regions, extending long in the first direction D1, of the sacrificial layers SAL and the active layers ACL. One active layer ACL may be separated into the semiconductor patterns SP adjacent to each other in the first direction D1 during the process of forming the third holes HL3. The semiconductor pattern SP may include the first semiconductor pattern SP1 and the second semiconductor pattern SP2 adjacent to each other in the second direction D2. The sacrificial layers SAL may be exposed to the outside again during the process of forming the third holes HL3.

The exposed sacrificial layers SAL may be entirely removed from the substrate 100 through the third holes HL3. Accordingly, second inner regions INR2 may be formed between regions of the active layers ACL not overlapping the second preliminary filling patterns PF2 (see FIG. 12). The first preliminary filling patterns PF1 (see FIG. 11) may be entirely removed from the substrate 100 during the removing process. Thereafter, third preliminary filling patterns PF3 may be formed to fill the second inner regions INR2, regions in which the first preliminary filling patterns PF1 (see FIG. 11) are removed, and the insides of the third holes HL3. The third preliminary filling patterns PF3 may include a single layer or a composite layer including an insulating material. For example, the third preliminary filling patterns PF3 may include at least one of silicon oxide and silicon nitride.

Thereafter, the second preliminary filling pattern PF2 (see FIG. 12) may be removed from the substrate 100. A gate dielectric layer Gox and a preliminary gate conductive layer PGE may be sequentially formed in the first inner regions INR1, and may constitute a preliminary word line PWL. The gate dielectric layer Gox and the preliminary gate conductive layer PGE may be formed to partially sequentially conformally cover the semiconductor pattern SP. The gate dielectric layer Gox and the preliminary gate conductive layer PGE may be formed to partially surround and cover the semiconductor pattern SP. One gate dielectric layer Gox and one preliminary gate conductive layer PGE may be formed to partially surround and cover the semiconductor patterns SP disposed in the first and third directions D1 and D3. Thereafter, the interlayered insulating layer ILD may be formed in a region in which the first inner regions INR1 and the second preliminary filling pattern PF2 are removed. A preliminary void SMp may be formed inside the interlayered insulating layer ILD during the process of forming the interlayered insulating layer ILD. For example, the preliminary void SMp may refer to a seam formed therein during a process of filling a trench having a high aspect ratio.

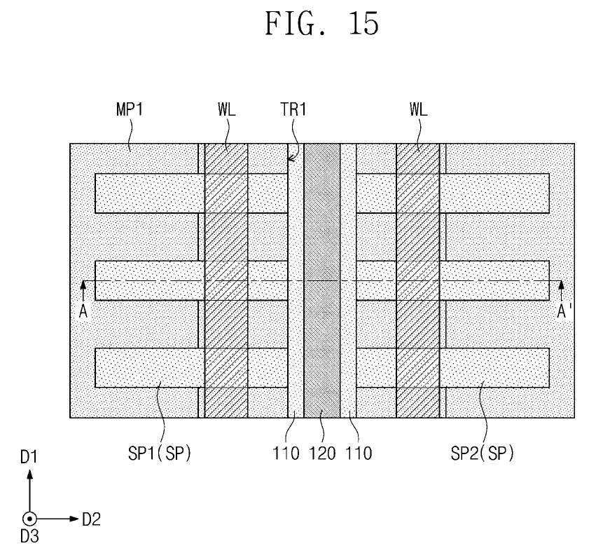

Referring to FIGS. 15 and 16, a first mask pattern MP1 may be formed on the semiconductor pattern SP and the third preliminary filling pattern PF3. The first mask pattern MP1 may not be formed in a region between the adjacent first and second semiconductor patterns SP1, SP2. An etching process may be performed using the first mask pattern MP1 as an etch mask to form a first trench TR1. The first trench TR1 may extend in the first direction D1, and may expose a sidewall of the semiconductor pattern SP and a sidewall of the interlayered insulating layer ILD.

Thereafter, the first lower liner pattern 110 and the first upper liner pattern 120 may be formed to conformally fill the first trench TR1. Forming the first lower liner pattern 110 and the first upper liner pattern 120 may include conformally depositing a first lower liner layer in the first trench TR1, filling the first trench TR1 with a first upper liner layer, and performing a planarization process on the first lower liner layer and the first upper liner layer. Due to a high aspect ratio of the first trench TR1, the first upper liner pattern 120 may include a first void SM1 formed therein.

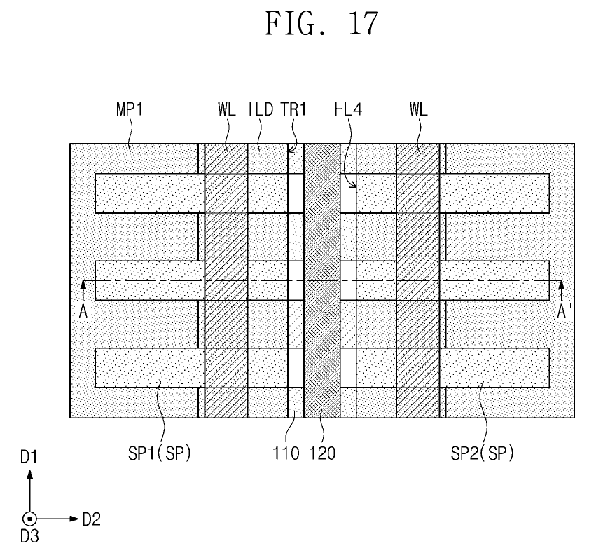

Referring to FIGS. 17 and 18, fourth holes HL4 may be formed between the semiconductor pattern SP and the first upper liner pattern 120. An upper portion of the first upper liner pattern 120 may be partially removed during the process of forming the fourth holes HL4. The fourth holes HL4 may be formed by removing a portion of the first lower liner pattern 110. As the fourth holes HL4 are formed and a cleaning process is performed, the sidewall of the interlayered insulating layer ILD and the sidewall of the semiconductor pattern SP may be exposed again.

For example, the void (or seam) may be formed in a filler material during filling of the first trench TR1 due to the high aspect ratio of the first trenches TR1. Accordingly, the process of exposing the sidewalls of the semiconductor pattern SP and the process of cleaning may expose the void and manufacturing process need to be more accurately controlled and managed.

In some implementations, the first upper liner pattern 120 may be formed in the first trench TR1, which has a property relatively harder(or denser) than that of the interlayered insulating layer ILD and the first lower liner pattern 110. In other words, the first upper liner pattern 120 may have a denser and mechanically stronger film quality than that of the interlayered insulating layer ILD and the first lower liner pattern 110. The first void SM1 (or seam) may be formed in the first upper liner pattern 120, and the first upper liners pattern 120 may have etching selectivity such that the first void SM1 may not be exposed to the outside. Therefore, the influence of the first void SM1 in the manufacturing process of the three-dimensional semiconductor device can be minimized. Accordingly, a reliability of the three-dimensional semiconductor device can be improved.

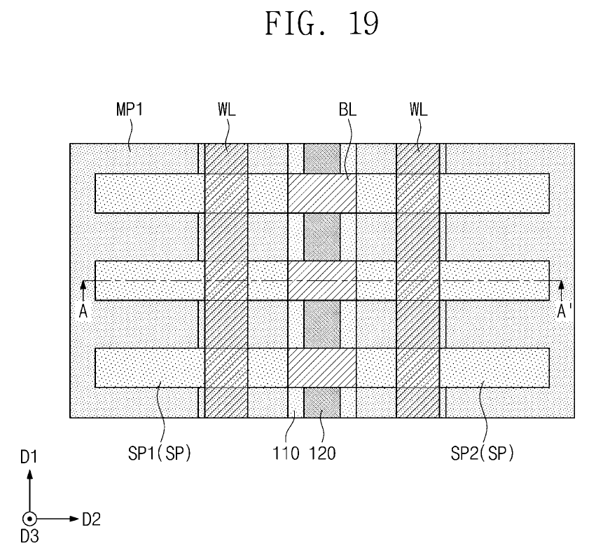

Referring to FIGS. 19 and 20, the bit lines BL may be formed so as to fill the fourth holes HL4. Forming the bit lines BL may include filling a conductive material into the fourth holes HL4, and planarizing the conductive material.

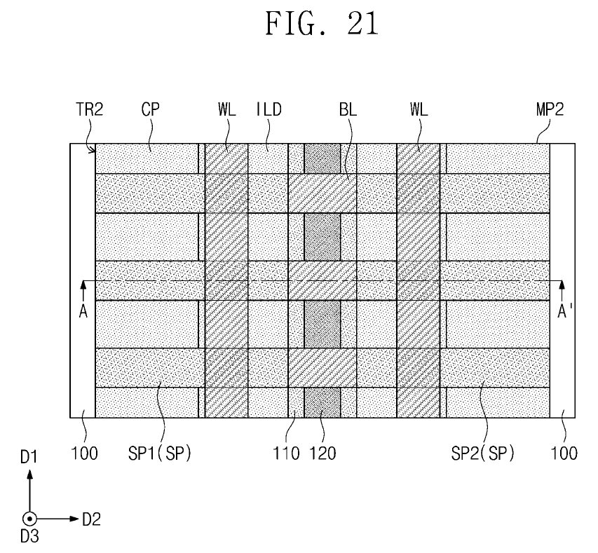

Referring to FIGS. 21 and 22, the first mask pattern MP1 may be removed, and the upper surface of the semiconductor pattern SP may be exposed. Removing the first mask pattern MP1 may include performing a planarization process. The third preliminary filling patterns PF3 (see FIG. 20) may be removed from the substrate 100. Each of the gate dielectric layer Gox and the preliminary gate conductive layer PGE may be partially removed together during the process of removing the third preliminary filling patterns PF3 (see FIG. 20). Accordingly, one gate dielectric layer Gox may be separated into a plurality of gate dielectric layers Gox disposed along the third direction D3. In addition, one preliminary gate conductive layer PGE may be separated into a plurality of gate electrodes GE disposed along in the third direction D3. The gate dielectric layer Gox and the gate electrode GE may constitute the word line WL.

The capping pattern CP may be formed in a region in which the third preliminary filling pattern PF3 (see FIG. 20) is removed. The capping pattern CP may include a first capping pattern CP1 and a second capping pattern CP2.

A second mask pattern MP2 covering the semiconductor pattern SP and the bit line BL may be formed. An etching process may be performed using the second mask pattern MP2 as an etch mask and a second trench TR2 may be formed. The second trench TR2 may be formed by removing a portion of the capping pattern CP. The second trench TR2 may extend in the first direction D1 and may expose a sidewall of the semiconductor pattern SP and a sidewall of the capping pattern CP.

Referring to FIGS. 23 and 24, third semiconductor patterns SP3 adjacent to the first semiconductor patterns SP1 along the second direction D2 may be provided. The third semiconductor patterns SP3 and the word lines WL and the capping pattern CP surrounding the third semiconductor patterns SP3 may be formed in substantially the same manufacturing method as described above in FIGS. 8 to 22. The second mask pattern MP2 may not be formed in a region between the first and third semiconductor patterns SP1, SP3 adjacent to each other. The second lower liner pattern 130 and the second upper liner pattern 140 may be formed to conformally fill the second trench TR2. Forming the second lower liner pattern 130 and the second upper liner pattern 140 may include conformally depositing a second lower liner layer in the second trench TR2, filling the second upper liner layer in the second trench TR2, and performing a planarization process on the second lower liner layer and the second upper liner layer. Due to a high aspect ratio of the second trench TR2, the second upper liner pattern 140 may include a second void SM2 formed therein.

Referring to FIGS. 25 and 26, a portion of the second lower liner pattern 130 may be selectively removed. Removing a portion of the second lower liner pattern 130 may be performed by a dry etch process or a wet etch process. A portion of the second upper liner pattern 140 may be removed during the process of removing a portion of the second lower liner pattern 130.

Thereafter, a portion of the capping pattern CP may be removed. The second edge portions EA2 of the semiconductor pattern SP may be exposed during the removing process. A portion of the second lower liner pattern 130 may be further removed during the removing process. A cleaning process may be performed on the second edge portions EA2 of the semiconductor pattern SP.

For example, a void (or a seam) may be formed in the filler material (e.g., the third preliminary filling pattern PF3 of FIG. 20) during the filling of the second trench TR2 due to the high aspect ratio of the second trenches TR2. Accordingly, the process of exposing the sidewalls of the semiconductor pattern SP and the process of cleaning may expose the void and manufacturing process need to be more accurately controlled and managed.

According to some implementations, a second upper liner pattern 140 may be formed in the first trench TR2, which has a film property relatively harder than that of the second lower liner pattern 130 and the capping pattern CP. The second void SM2 (or seam) may be formed in the second upper liner pattern 140, and the second upper liners pattern 140 may have etching selectivity such that the second void SM2 may not be exposed to the outside. Therefore, the influence of the second void SM2 in the manufacturing process of the three-dimensional semiconductor device can be minimized. Accordingly, the reliability of the three-dimensional semiconductor device can be improved.

Referring to FIG. 27, storage electrodes SE may be formed on the second edge portions EA2 of the semiconductor patterns SP. For example, forming the storage electrodes SE may include forming silicide patterns (not shown) on the second edge portions EA2 of the semiconductor patterns SP, and forming the storage electrodes SE through a selective epitaxial growth (SEG) process using the silicide patterns as seeds. Hereafter, a portion of the semiconductor pattern SP adjacent to the storage electrode SE may be referred to the second edge portion EA2.

A dielectric layer CIL may be formed to conformally cover the storage electrodes SE. A plate electrode PE may be formed so as to fill spaces between the storage electrodes SE. As the storage electrode SE, the dielectric film CIL, and the plate electrode PE are formed, the data storage pattern DSP may be formed.

Referring back to FIGS. 3, 4a, 6 and 7a, the second mask pattern MP2 may be removed, and the upper surface of the semiconductor pattern SP may be exposed. An upper insulating layer UIL covering the data storage pattern DSP, the bit line BL, and the semiconductor pattern SP may be formed.

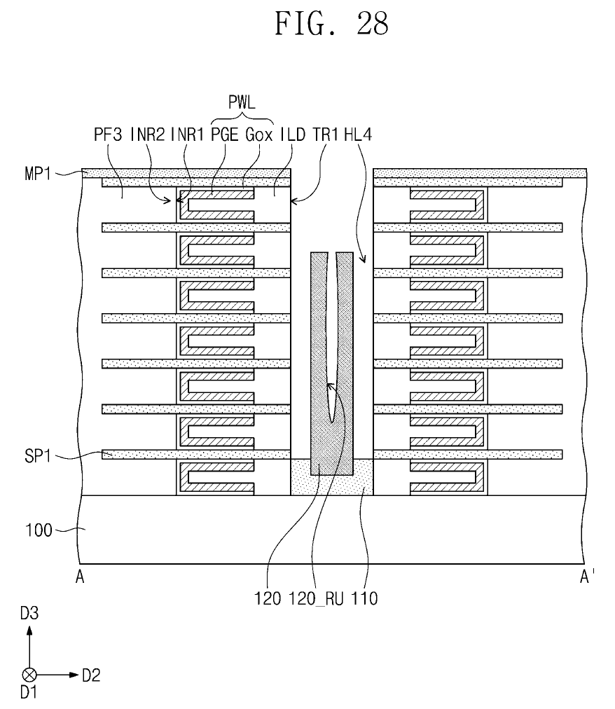

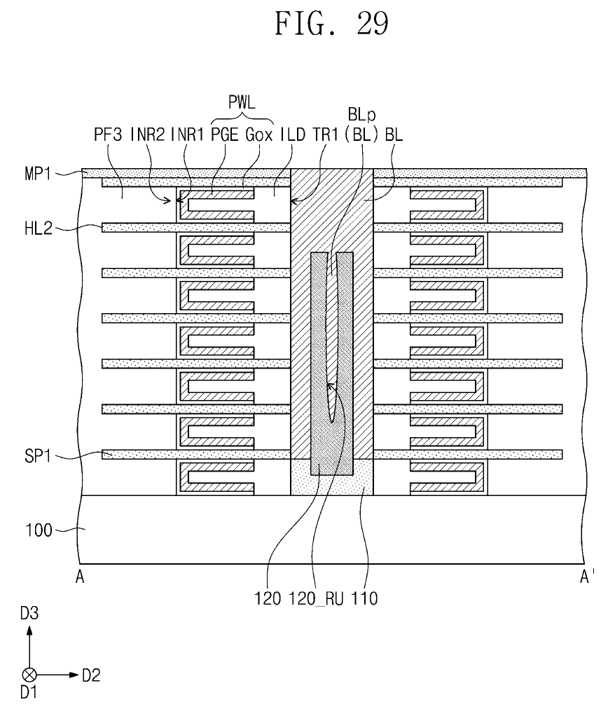

FIGS. 28 and 29 are diagrams illustrating a method for manufacturing a three-dimensional semiconductor device according to some implementations. Specifically, FIG. 28 is a cross-sectional view corresponding to FIGS. 18, and 29 is a cross-section view corresponding to FIG. 20.

Referring to FIG. 28, after the forming process of the first lower liner pattern 110 and the first upper liner pattern 120 described with reference to FIGS. 15 and 16, a portion of the first upper liners pattern 120 may be further removed during the process of forming the fourth holes HL4. For example, the portion of the first upper liner pattern 120 may be further removed such that an upper portion of the first void SM1 (See FIG. 16) of the first upper liner pattern 120 is exposed. Accordingly, the first upper liner pattern 120 may have the recessed top surface 120_RU. The first void SM1 (See FIG. 16) of the first upper liner pattern 120 may not be exposed in a horizontal direction or a direction toward the substrate 100.

Referring to FIG. 29, the bit lines BL may be formed in the fourth holes HL4. Each of the bit lines BL may include a first protrusion part BLp that protrudes toward the recessed top surface 120_RU of the first upper liner pattern 120. The first protrusion part BLp of each of the bit lines BL may cover the recessed top surface 120_RU of the first upper liner pattern 120.

In some implementations, a lower liner pattern and an upper liner pattern may be disposed between the bit lines and the substrate or between the data storage pattern and the substrate. In other words, the lower liner pattern and the upper liner pattern may be disposed in a trench between first and second semiconductor patterns adjacent to each other. Although a void (or a seam) may be formed in the upper liner pattern due to a high aspect ratio of the trenches, the upper liner patterns may have a property relatively harder than that of the lower liner patterns. As a result, the influence of voids may be reduced during forming the trench and performing the cleaning process in the process of manufacturing the three-dimensional semiconductor device according some examples. Accordingly, the reliability of the three-dimensional semiconductor device can be improved.

In some aspects, the present disclosure provides a method of manufacturing a three-dimensional semiconductor device that may include forming first semiconductor patterns on a substrate and spaced apart from each other in a first direction parallel to a lower surface of the substrate, forming second semiconductor patterns adjacent to the first semiconductor patterns in a second direction parallel to the lower surface of the substrate, the second semiconductor patterns are spaced apart from each other in the first direction, forming a first trench extending in the first direction between the first semiconductor patterns and the semiconductor patterns, forming a lower liner layer conformally covering the first trench, forming an upper liner layer filling the first trench on the lower liner layer, etching a portion of the lower liner layer to expose sidewalls of the first semiconductor patterns, and forming bit lines on the exposed sidewalls of the first semiconductor patterns.

In some implementations, the lower liner layer may have etching selectivity with respect to the upper liner layer.

In some implementations, forming the first trench may include exposing sidewalls of the first semiconductor patterns and sidewalls of the second semiconductor patterns.

In some implementations, the upper liner layer may include a void formed therein.

In some implementations, the method of manufacturing the three-dimensional semiconductor device may include etching a portion of the lower liner layer to expose sidewalls of the second semiconductor patterns before forming the bit lines, where the bit lines disposed on the exposed sidewalls of the second semiconductor.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A three-dimensional semiconductor device comprising:
a substrate;
a plurality of first semiconductor patterns on the substrate and spaced apart from each other in a first direction parallel to a lower surface of the substrate;
a plurality of second semiconductor patterns (i) adjacent to the plurality of first semiconductor patterns in a second direction perpendicular to the first direction and parallel to the lower surface of the substrate, and (ii) spaced apart from each other in the first direction;
a lower liner pattern on the substrate and extending in the first direction between the plurality of first semiconductor patterns and the plurality of second semiconductor patterns;
an upper liner pattern extending in the first direction on the lower liner pattern; and
a plurality of bit lines between (i) the plurality of first semiconductor patterns and the (ii) upper liner pattern, and between (i) the plurality of second semiconductor patterns and (ii) the upper liner pattern,
wherein the plurality of bit lines extend, on the lower liner pattern, in a third direction perpendicular to the first direction and the second direction.

2. The three-dimensional semiconductor device of claim 1, wherein the lower liner pattern comprises (i) a horizontal portion that vertically overlaps with the upper liner pattern, and (ii) a plurality of vertical portions that protrude, from a first end and a second end of the horizontal portion, in the third direction, and
wherein the plurality of vertical portions partially cover a plurality of sidewalls of the upper liner pattern.

3. The three-dimensional semiconductor device of claim 2, wherein the plurality of vertical portions comprise a first portion vertically overlapping with the plurality of bit lines relative to the substrate, and a second portion adjacent to the first portion in the first direction, wherein an upper surface of the first portion is at a lower level than an upper surface of the second portion.

4. The three-dimensional semiconductor device of claim 1, wherein the upper liner pattern comprises a different material from the lower liner pattern.

5. The three-dimensional semiconductor device of claim 1, wherein the plurality of bit lines connect the plurality of first semiconductor patterns and the plurality of second semiconductor patterns, and
wherein the plurality of bit lines cross the lower liner pattern and the upper liner pattern.

6. The three-dimensional semiconductor device of claim 1, comprising a plurality of word lines crossing the plurality of first semiconductor patterns and the plurality of second semiconductor patterns and extending in the first direction,
wherein the word lines are spaced apart from the upper liner pattern in the second direction.

7. The three-dimensional semiconductor device of claim 1, wherein the upper liner pattern comprises a recessed upper surface, and
wherein each of the plurality of bit lines comprises a protrusion portion protruding into the recessed upper surface of the upper liner pattern.

8. The three-dimensional semiconductor device of claim 1, wherein each of the plurality of bit lines comprises a first bit line and a second bit line spaced apart from each other in the second direction, and
wherein the upper liner pattern is between the first bit line and the second bit line.

9. The three-dimensional semiconductor device of claim 1, wherein the upper liner pattern defines a cavity therein.

10. A three-dimensional semiconductor device comprising:
a substrate;
a plurality of first semiconductor patterns on the substrate and spaced apart from each other in a first direction parallel to a lower surface of the substrate;
a plurality of bit lines on a plurality of first sidewalls of the first semiconductor patterns;
a data storage pattern on a plurality of second sidewalls of the first semiconductor patterns opposite to the first sidewalls of the first semiconductor patterns in a second direction, the second direction being perpendicular to the first direction and parallel to the lower surface of the substrate;
a lower liner pattern between the data storage pattern and the substrate; and
an upper liner pattern between the data storage pattern and the lower liner pattern,
wherein the lower liner pattern and the upper liner pattern extend in the first direction.

11. The three-dimensional semiconductor device of claim 10, wherein the data storage pattern covers an upper surface of the lower liner pattern and an upper surface of the upper liner pattern.

12. The three-dimensional semiconductor device of claim 10, wherein the lower liner pattern comprises (i) a horizontal portion vertically overlapping with the upper liner pattern and (ii) a plurality of vertical portions protruding in a third direction from a first end and a second end of the horizontal portion, the third direction being perpendicular to the first direction and the second direction, and
wherein the plurality of vertical portions partially cover a plurality of sidewalls of the upper liner pattern.

13. The three-dimensional semiconductor device of claim 10, wherein the data storage pattern comprises:
a storage electrode on the plurality of second sidewalls of the first semiconductor patterns;
a plate electrode on the storage electrode; and
a dielectric layer between the storage electrode and the plate electrode,
wherein the upper liner pattern is between the plate electrode and the substrate.

14. The three-dimensional semiconductor device of claim 13, wherein the dielectric layer covers a sidewall of the lower liner pattern and a sidewall of the upper liner pattern.

15. The three-dimensional semiconductor device of claim 13, wherein the upper liner pattern comprises a recessed upper surface, and
wherein the plate electrode comprises a protrusion portion protruding into the recessed upper surface of the upper liner pattern.

16. The three-dimensional semiconductor device of claim 15, wherein the dielectric layer is interposed between (i) the protrusion portion of the plate electrode and (ii) the upper liner pattern.

17. The three-dimensional semiconductor device of claim 10, wherein the upper liner pattern and the lower liner pattern comprise different materials.

18. The three-dimensional semiconductor device of claim 10, wherein the upper liner pattern defines a cavity therein.

19. A three-dimensional semiconductor device comprising:
a substrate;
a plurality of first semiconductor patterns on the substrate and spaced apart from each other in a first direction parallel to a lower surface of the substrate;
a plurality of second semiconductor patterns adjacent to a plurality of first edge portions of the plurality of first semiconductor patterns in a second direction perpendicular to the first direction and parallel to the lower surface of the substrate;
a plurality of third semiconductor patterns adjacent to a plurality of second edge portions of the plurality of first semiconductor patterns in the second direction;
a first lower liner pattern on the substrate and extending in the first direction between the first semiconductor patterns and the second semiconductor patterns;
a first upper liner pattern on the first lower liner pattern and extending in the first direction;
a plurality of bit lines on the plurality of first edge portions of the plurality of first semiconductor patterns and extending in a third direction perpendicular to the first and second directions; and
data storage pattern extending in the third direction on the second edge portions of the first semiconductor patterns,
wherein the bit lines are between (i) the plurality of first edge portions and (ii) the first upper liner pattern, on the first lower liner pattern.

20. The three-dimensional semiconductor device of claim 19, comprising:
a second lower liner pattern between the data storage pattern and the substrate; and
a second upper liner pattern between the data storage pattern and the second lower liner pattern,
wherein the second lower liner pattern and the second upper liner pattern extend in the first direction.
